(19) United States
(12) Patent Application Publication
(10) Pub. No.: US 2018/0090041 A1
(43) Pub. Date: Mar. 29, 2018

(54) PANEL TESTING UNIT, ARRAY SUBSTRATE AND LIQUID CRYSTAL DISPLAY DEVICE

(71) Applicant: SHENZHEN CHINA STAR OPTOELECTRONICS TECHNOLOGY CO., LTD., Shenzhen (CN)

(72) Inventor: Qiming GAN, Shenzhen (CN)

(73) Assignee: SHENZHEN CHINA STAR OPTOELECTRONICS TECHNOLOGY CO., LTD., Shenzhen (CN)

(21) Appl. No.: 15/126,585

(22) PCT Filed: Jun. 13, 2016
(86) PCT No.: PCT/CN2016/085594

§ 371 Date: Sep. 16, 2016

(30) Foreign Application Priority Data
May 6, 2016 (CN) 201610298412.7

(51) Int. Cl. G09G 3/00; G09G 3/36; H01L 27/105; G02F 1/13

(52) U.S. Cl. CPC G09G 3/006; G09G 3/3611; G02F 1/1309; H01L 27/105; G09G 3/3648

(57) ABSTRACT

A panel testing unit is provided, an array substrate including the panel testing unit and a liquid crystal display device including the array substrate. The panel testing unit includes at least a shorting bar set, each shorting bar set including at least a shorting line; at least a signal line set, each signal line set including at least a signal line. Any one of the signal lines is connected to a corresponding one of the shorting lines through a diode. A novel technical scheme is provided, a unidirectional diode is disposed between the signal line and the shorting line (test line), after the test is finished, a laser cutting process is not necessary, a processing of a next step can be performed directly, thus the processing cost is reduced, and the productivity is increased.

### FIELD OF THE INVENTION

The present invention relates to a liquid crystal display technology, and particularly to a panel testing unit, an array substrate including the panel testing unit, and a liquid crystal display device including the panel array substrate.

### BACKGROUND OF THE INVENTION

The main structure of a thin film transistor liquid crystal display (TFT-LCD) includes a liquid crystal panel and a backlight module, the liquid crystal panel includes an array substrate, a color film substrate and a liquid crystal cell disposed therebetween.

In the process of manufacturing the display, before the LCD light panel is combined with IC, it is necessary to perform lighting test on the liquid crystal cell, to sieve out a poor product, and prevent it from entering the next step of the process, in order to decrease the cost of the subsequent process. Signal lines corresponding to single-color data lines one by one are disposed on the array substrate. When executing a liquid crystal cell test, signal lines having the same test signal are shorted to the same shorting bar by inputting a test signal to a guide pin/guide lead corresponding to each signal line.

In the existing technology, the panel testing unit of the processing of the RGB liquid crystal display, as shown in FIG. 1, generally includes three (R/G/B) shorting bars 111, 112, 113, connected to three pixel signal lines 211, 212, 213 by guide leads, respectively, for lighting bright white/pure, red/pure, green/pure blue pictures in the stage of the liquid crystal cell test, to check the display quality of the panel, thereby determining whether there is open circuit or defect on the pixel signal line. After the test is finished, the connection between the shorting line (test line) and the signal line is cut by laser cutting.

Because it is necessary to use laser to cut the test line after the liquid crystal display panel is tested by the test circuit of the aforementioned liquid crystal display panel, thus a laser cutting process is required. As the process is increased, the productivity of the liquid crystal display panel is decreased; the panel may be damaged in the process of the laser cutting, and thus affect the product yield. The productivity being decreased and the product yield being decreased both increase the cost of producing the liquid crystal panel. Therefore, in the practical manufacturing, each member of R&D personnel has to think how to decrease the manufacturing process to the possibility, in order to increase the productivity and decrease the production cost.

### SUMMARY OF THE INVENTION

An objective of the present invention is to solve the technical problems of increased processes, decreased productivity, and higher production costs in the manufacturing process of the existing liquid crystal display.

To achieve the above objective, the present invention provides a panel testing unit, including: at least a shorting bar set, each shorting bar set including at least a shorting line; at least a signal line set, each signal line set including at least a signal line. Any one of the signal lines is connected to a corresponding one of the shorting lines through a diode.

Preferably, the shorting bar set includes at least a first shorting bar set and/or at least a second shorting bar set.

Preferably, the signal line set includes at least a first signal line set and/or at least a second signal line set.

Preferably, the first shorting bar set includes a first shorting line, a second shorting line and a third shorting line.

Preferably, the first signal line set includes: an R pixel signal line, connected to the first shorting line through a diode; an anode of the diode connected to the first shorting line, a cathode of the diode connected to the R pixel signal line; a G pixel signal line, connected to the second shorting line through a diode; an anode of the diode connected to second shorting line, a cathode of the diode connected to the G pixel signal line; and a B pixel signal line, connected to the third shorting line through a diode; an anode of the diode connected to third shorting line, a cathode of the diode connected to the B pixel signal line.

Preferably, the second shorting bar set includes a fourth shorting line and a fifth shorting line.

Preferably, the second signal line set includes: an odd signal line, connected to the fourth shorting line through a diode; an anode of the diode connected to the fourth shorting line, a cathode of the diode connected to the odd signal line; and an even signal line, connected to the fifth shorting line through a diode; an anode of the diode connected to the fifth shorting line, a cathode of the diode connected to the even signal line.

Preferably, the diode is a Schottky diode.

To achieve the above objective, the present invention provides an array substrate, including: a display area, with a liquid crystal and at least a data line set disposed therein; and a non-display area, disposed around the display area, with at least one panel testing unit mentioned above.

Preferably, the data line set includes: an R pixel data line, connected to the R pixel signal line; a G pixel data line, connected to the G pixel signal line; and a B pixel data line, connected to the B pixel signal line.

Preferably, the data line set includes: an odd data line, connected to the odd signal line; and an even data line, connected to the even signal line.

To achieve the above objective, the present invention provides a liquid crystal display device, including the aforementioned array substrate.

The advantage of the present invention is that it provides a novel technical scheme, an unidirectional diode is disposed between the signal line and the shorting line (test line), after the test is finished, a laser cutting process is not necessary, a processing of a next step can be performed directly, thus the processing cost is reduced, and the productivity is increased.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a structural diagram of an RGB panel testing unit of the prior art;

FIG. 2 illustrates a structural diagram of a panel testing unit according to an embodiment of the present invention;

FIG. 3 illustrates an entire structural diagram of an array substrate according to an embodiment of the present invention;

FIG. 4 illustrates a partly enlarged view of the first shorting bar set and the pixel data line set in FIG. 3;

FIG. 5 illustrates a partly enlarged view of the second shorting bar set and the odd and even data line set in FIG. 3; and

FIG. 6 illustrates a structural diagram of a liquid crystal display device according to an embodiment of the present invention.

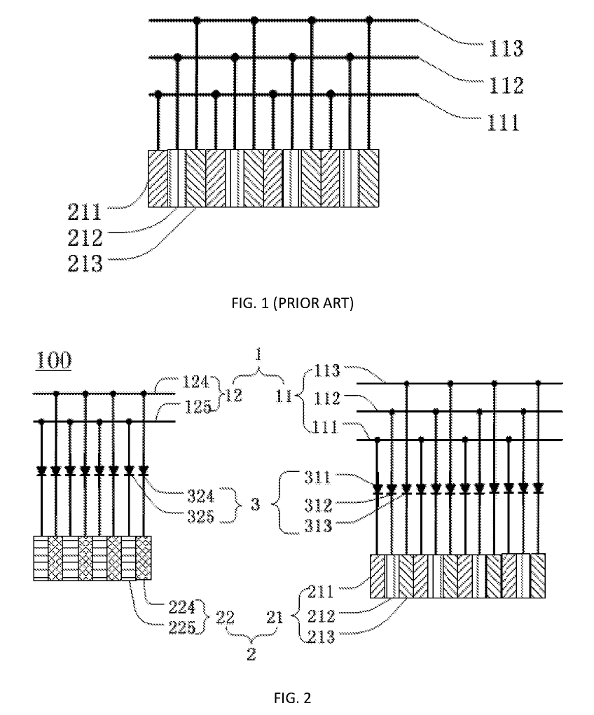

### DETAILED DESCRIPTION OF THE PREFERRED EMBODIMENTS

To achieve the above-mentioned objects and effects, the techniques, measures, and structure of the present invention are illustrated in the figures and descriptions of preferred embodiments below.

As shown in FIG. 2, the embodiment provides a panel testing unit 100, including: at least a shorting bar set 1, each shorting bar set includes at least a shorting line; at least a signal line set 2, each signal line set includes at least a signal line; wherein, any signal line is connected to a shorting line corresponding to the signal line through an unidirectional diode 3, an anode of the diode 3 is connected to the shorting line, a cathode of the diode 3 is connected to the signal line. The diode 3 is a Schottky diode.

In the embodiment, the shorting bar set 1 includes at least a first shorting bar set 11 and at least a second shorting bar set 12. The signal line set 2 includes at least a first signal line set 21 and at least a second signal line set 22. In other embodiment, the shorting bar set 1 includes at least a first shorting bar set 11 or at least a second shorting bar set 12. The signal line set 2 includes at least a first signal line set 21 or at least a second signal line set 22.

The first shorting bar set 11 includes a first shorting line 111, a second shorting line 112 and a third shorting line 113. The first signal line set 21 includes: an R pixel signal line 211, connected to first shorting line 111 through a diode 311; an anode of the diode 311 connected to first shorting line 111, a cathode of the diode 311 connected to the R pixel signal line 211; a G pixel signal line 212, connected to second shorting line 112 through a diode 312; an anode of the diode 312 connected to the second shorting line 112, a cathode of the diode 312 connected to the G pixel signal line 212; and a B pixel signal line 213, connected to third shorting line 113 through a diode 313; an anode of the diode 313 connected to third shorting line 113, a cathode of the diode 313 connected to the B pixel signal line 313.

The second shorting bar set 12 includes a fourth shorting line 124 and a fifth shorting line 125. The second signal line set 22 includes: an odd signal line 224, connected to fourth shorting line 124 through a diode 324; an anode of the diode 324 connected to a fourth shorting line 124, a cathode of the diode 324 connected to odd signal line 224; and an even signal line 225, connected to fifth shorting line 125 through a diode 325; an anode of the diode 325 connected to fifth shorting line 125, a cathode of the diode 325 connected to the even signal line 225.

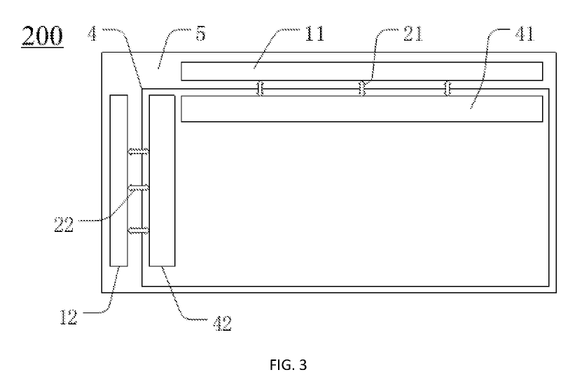

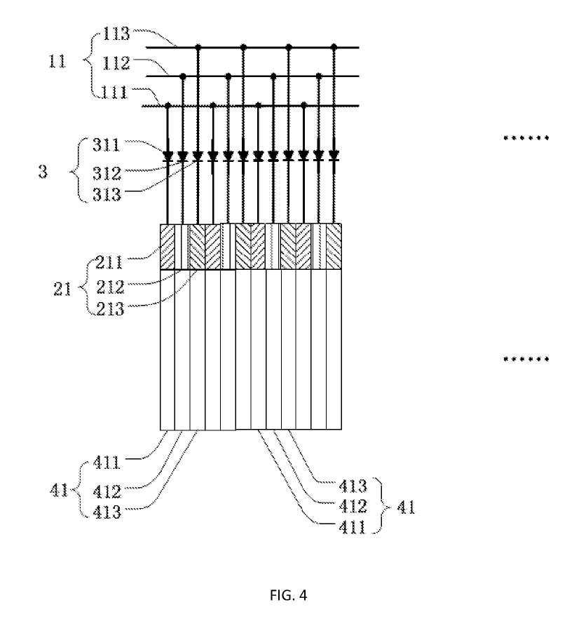

As shown in FIGS. 3-5, the embodiment provides an array substrate 200, including a display area 4 and a non-display area 5, the display area 4 having a liquid crystal and a plurality of data line sets disposed therein, such as a pixel data line set 41, an odd and even data line set 42; a non-display area 5 disposed around the display area 4, having a plurality of the panel testing units 100 disposed therein. In the embodiment, the shorting bar set 1 includes a first shorting bar set 11 and a second shorting bar set 12, the pixel data line set 41 connected to first signal line set 21, the odd and even data line set 42 connected to the second shorting bar set 12. As shown in FIG. 4, the pixel data line set 41 includes: an R pixel data line 411, connected to the R pixel signal line 211; a G pixel data line 412, connected to the G pixel signal line 212; and a B pixel data line 413, connected to the B pixel signal line 213. As shown in FIG. 5, the odd and even data line set 42 includes: an odd data line 424, connected to the odd signal line 224; and an even data line 425, connected to the even signal line 225.

In the embodiment, the R pixel data line 411 is connected to the first shorting line 111, through the R pixel signal line 211 connected to the first shorting line 111, inputting a test signal through a test signal point on the first shorting line 111, the diode is turned on at this moment, red color can be lit below the display area, it is tested below the pure red color whether there is a strange pixel point or uneven brightness (Mura), and whether there is a short circuit on the trace (fanout trace) of the test wiring, and other lighting test conditions. Similarly, pure blue, pure green, pure white (three colors lit at the same time) can also be lit, to check if there is a short circuit, or a defective point existing.

Because all of the diodes are unidirectional, though all shorting lines remain on the liquid crystal panel after the test, it will not affect the normal operation of the liquid crystal panel, thus the shorting line does not need to be cut. After the lighting test, it is not necessary to perform the laser cutting process, the next stage of the processing can be performed directly, thus the manufacturing cost is decreased, and the productivity is increased.

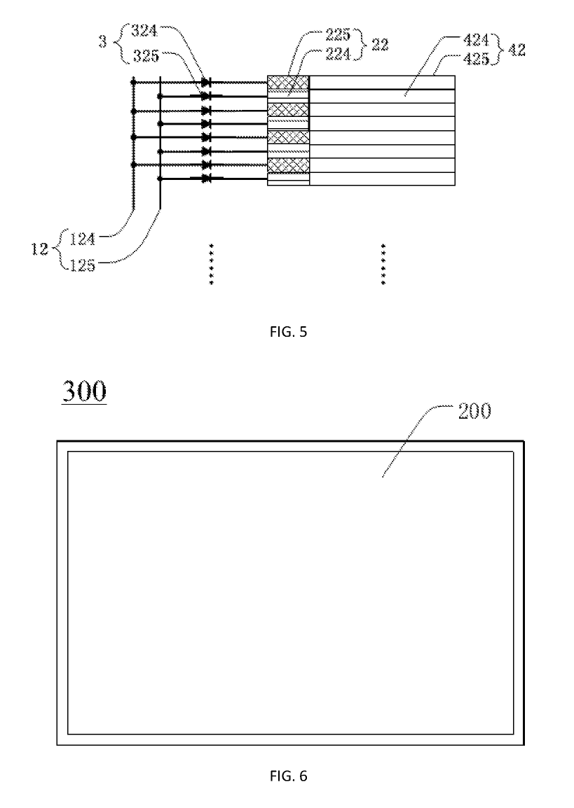

As shown in FIG. 6, the embodiment provides a liquid crystal display device 300, including the aforementioned array substrate 200 and other components should be of the display.

In summary, the technical scheme of the present invention uses the characteristic of the unidirectional diode, it can be optional to turn on/off the signal path between the signal line and the shorting line, without the need of laser cutting to cut the test line, an additional laser cutting step can be avoided, thus the process time of the liquid crystal display panel can be decreased, and the productivity of the liquid crystal display panel can be increased. On the other hand, the present invention can prevent the step of laser cutting from affecting the liquid crystal display panel, and increase the product yield of the liquid crystal display panel.

The fore-going preferred embodiments of the present invention are illustrative of the present invention rather than limiting of the present invention. It is intended to cover various modifications and changes included within the spirit and scope of the appended claims, the scope of which should be accorded the broadest interpretation so as to encompass all such modifications and similar structures.

1. A panel testing unit, comprising:
at least a shorting bar set, each shorting bar set including at least a shorting line; and
at least a signal line set, each signal line set including at least a signal line;
wherein any one of the signal lines is connected to a corresponding one of the shorting lines through a diode.

2. The panel testing unit of claim 1, wherein the shorting bar set includes at least a first shorting bar set and/or at least a second shorting bar set.

3. The panel testing unit of claim 1, wherein the signal line set includes at least a first signal line set and/or at least a second signal line set.

4. The panel testing unit of claim 2, wherein the first shorting bar set includes a first shorting line, a second shorting line, and a third shorting line.

5. The panel testing unit of claim 3, wherein the first signal line set includes:
an R pixel signal line, connected to the first shorting line through a diode; an anode of the diode connected to the first shorting line, a cathode of the diode connected to the R pixel signal line;
a G pixel signal line, connected to the second shorting line through a diode; an anode of the diode connected to second shorting line, a cathode of the diode connected to the G pixel signal line; and
a B pixel signal line, connected to the third shorting line through a diode; an anode of the diode connected to third shorting line, a cathode of the diode connected to the B pixel signal line.

6. The panel testing unit of claim 2, wherein the second shorting bar set includes a fourth shorting line and a fifth shorting line.

7. The panel testing unit of claim 3, wherein the second signal line set includes:
an odd signal line, connected to the fourth shorting line through a diode; an anode of the diode connected to the fourth shorting line, a cathode of the diode connected to the odd signal line; and
an even signal line, connected to the fifth shorting line through a diode; an anode of the diode connected to the fifth shorting line, a cathode of the diode connected to the even signal line.

8. The panel testing unit of claim 1, wherein the diode is a Schottky diode.

9. An array substrate, comprising:
a display area, with a liquid crystal and at least a data line set disposed therein; and
a non-display area, disposed around the display area, with at least one panel testing unit of claim 1.

10. The array substrate of claim 9, wherein the data line set includes:
an R pixel data line, connected to the R pixel signal line;
a G pixel data line, connected to the G pixel signal line; and
a B pixel data line, connected to the B pixel signal line.

11. The array substrate of claim 9, wherein the data line set includes:
an odd data line, connected to the odd signal line; and
an even data line, connected to the even signal line.

12. A liquid crystal display device, comprising the array substrate of claim 9.
